(19) United States
(12) Patent Application Publication
(10) Pub. No.: US 2009/0309139 A1
(43) Pub. Date: Dec. 17, 2009

(54) ASYMMETRIC GATE ELECTRODE AND METHOD OF MANUFACTURE

(75) Inventors: Andres BRYANT, Burlington, VT (US); Edward J. NOWAK, Essex Junction, VT (US)

Correspondence Address: GREENBLUM & BERNSTEIN, P.L.C., 1950 ROLAND CLARK DRIVE, RESTON, VA, 20191, US

(73) Assignee: INTERNATIONAL BUSINESS MACHINES CORPORATION, Armonk, NY (US)

(21) Appl. No.: 12/139,158

(22) Filed: Jun. 13, 2008

(51) Int. Cl. H01L 29/78; H01L 21/336

(52) U.S. Cl. 257/288; 438/286; 257/E29.255; 257/E21.427

(57) ABSTRACT

The invention relates to an asymmetric gate electrode and method of manufacturing an asymmetric gate electrode. The method includes: forming a source region and drain region in a substrate; forming a symmetrical gate structure over a channel formed between the source region and the drain region; depositing a material on the substrate and planarizing the material to a top of the symmetrical gate structure; recessing the symmetrical gate structure to below a surface of the material; forming spacers in the recess; protecting one edge of the spacer while etching another edge of the spacer to remove a portion thereof; and recessing the symmetrical gate structure on a side closest to the source region while the another edge of the spacer protects the symmetrical gate structure on a side closest to the drain region to form an asymmetrical gate electrode.

### FIELD OF THE INVENTION

The invention relates to an asymmetric gate electrode and method of manufacturing an asymmetric gate electrode.

### BACKGROUND

It is desirable to have a gate with a low gate-electrode resistance. This will minimize gate delay for wide devices, as well as minimize noise for RF applications. An increased gate height will minimize gate resistance.

It is also desirable to have low gate-to-drain capacitance. This minimizes gate delay in general, as well as maximizes Ft for RF applications. A decreased gate height will minimize gate-to-drain capacitance. Of course, through, the decreased gate height will increase gate resistance. And, to gain a low gate-electrode resistance, the increase in gate height will increase gate-to-drain capacitance.

The standard solution to this problem for RF devices is the so-called T-gate. In a T-gate, the gate electrode is wide at top for low resistance and narrow at the bottom for low gate-to drain capacitance. This results in large contacted pitch for digital logic applications since the top of the “T” block contacts. Also, this results in large outer-fringe capacitance from gate-to-drain and gate-to-source. Lastly, it is known that the T-gate requires complex processing to fabricate.

Accordingly, there exists a need in the art to overcome the deficiencies and limitations described hereinabove.

### SUMMARY

In a first aspect of the invention, a structure comprises an asymmetrical gate electrode with a taller side near a source region and a shorter side near a drain region and contacts on either side of the gate electrode, connecting to the source region and the drain region.

In another aspect of the invention, a method comprises: forming source region and drain region in a substrate; forming a symmetrical gate structure over a channel formed between the source region and the drain region; depositing a material on the substrate and planarizing the material to a top of the symmetrical gate structure; recessing the symmetrical gate structure to below a surface of the material; forming spacers in the recess; protecting one edge of the spacer on a source side of the symmetrical gate structure while etching another edge of the spacer to remove a portion thereof on a drain side of the symmetrical gate structure; and recessing the symmetrical gate structure on a side closest to the drain region while the another edge of the spacer protects the symmetrical gate structure on a side closest to the drain region to form an asymmetrical gate electrode.

### BRIEF DESCRIPTION OF THE SEVERAL VIEWS OF THE DRAWINGS

The present invention is described in the detailed description which follows, in reference to the noted plurality of drawings by way of non-limiting examples of exemplary embodiments of the present invention.

FIG. 1 shows an illustrative example of a gate electrode in accordance with the present invention;

FIG. 2 shows another illustrative example of a gate electrode in accordance with the present invention; and

FIGS. 3a-3h show structures and respective processing steps in accordance with the invention.

### DETAILED DESCRIPTION

The invention relates to an asymmetric gate electrode and method of manufacturing an asymmetric gate electrode. In embodiments, the gate-electrode of the present invention is constructed to be taller on the source side and shorter on the drain side of the channel. Advantageously, the design of the present invention results in a lower gate-to-drain capacitance than a conventional T-gate and/or conventional gate structure. Additionally, the present invention results in a lower gate-to-source capacitance than a conventional T-gate. The present invention also results in a high-density.

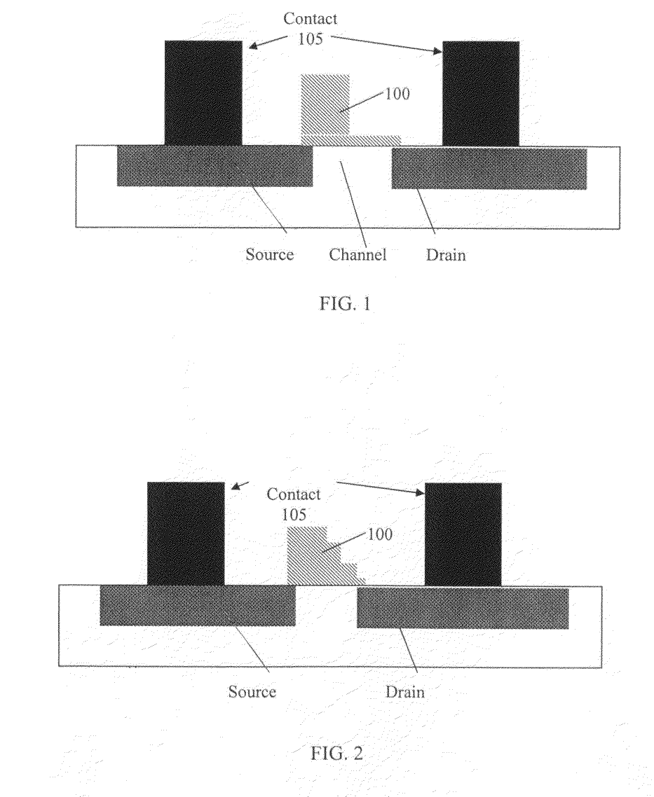

FIG. 1 shows an illustrative example of a gate electrode in accordance with the present invention. More specifically, as shown in FIG. 1, the gate electrode 100 is asymmetrical with a taller side near the source region and the shorter side near the drain region. FIG. 1 also shows contacts 105 on either side of the gate electrode 100, connecting to the source region and drain region, respectively.

The gate-electrode can be of arbitrary shape. For example, FIG. 2 shows another illustrative example of a gate electrode in accordance with the present invention. In this example, the gate electrode 100 is configured in a multiple stepped pattern. Again, the gate 100 is asymmetrical with a taller side near the source and the shorter side near the drain.

### Methods in Accordance with the Invention

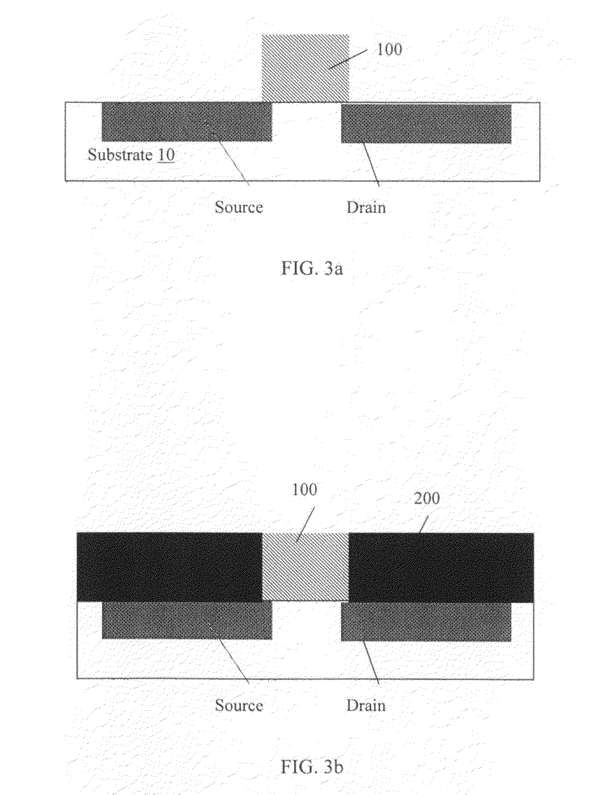

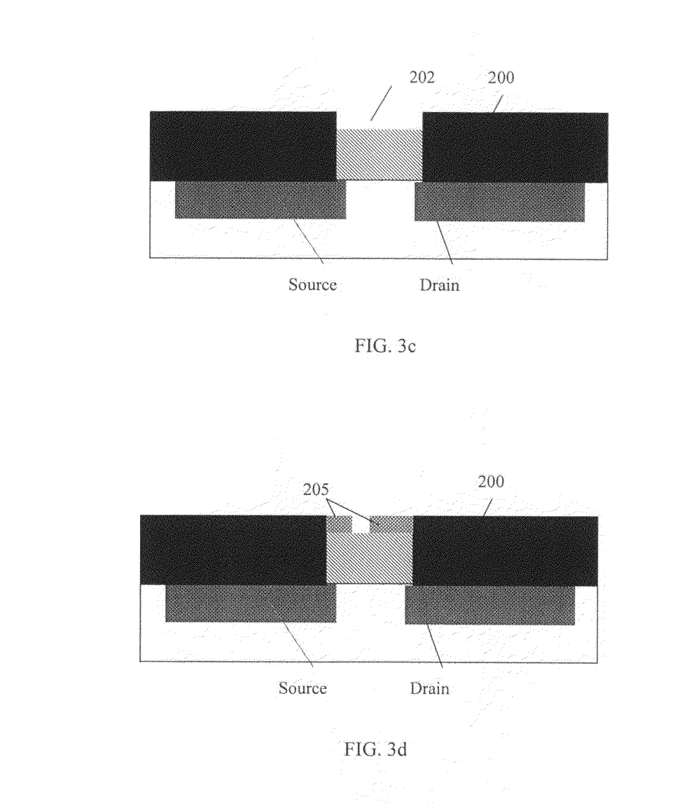

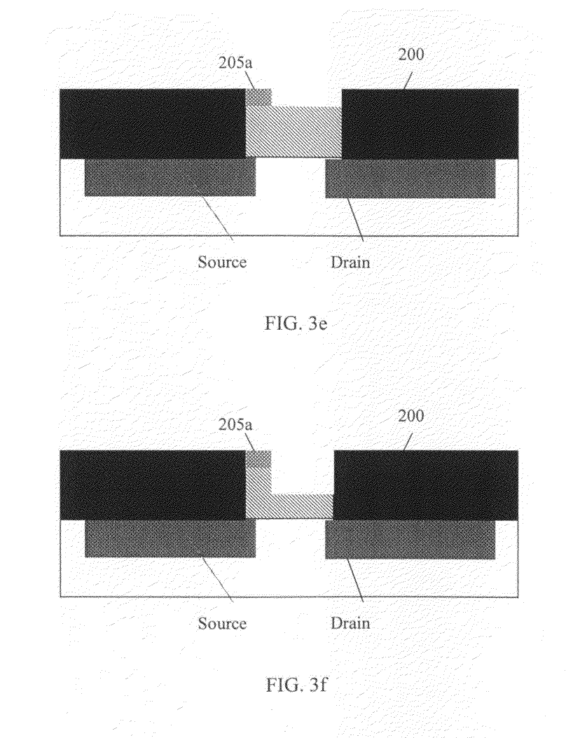

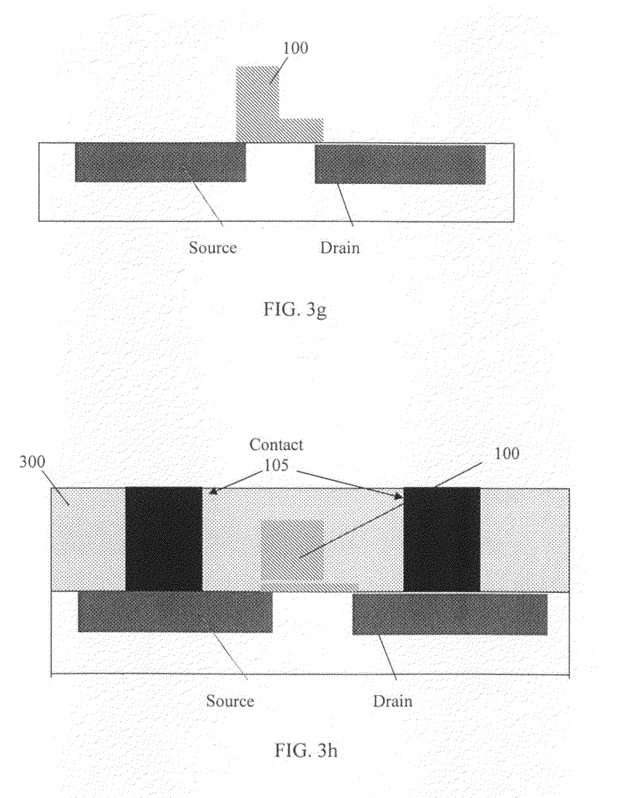

FIGS. 3a-3h show structures and respective processing steps in accordance with the invention. In particular, FIG. 3a shows a beginning structure with a conventional process flow up to the source and drain formation in a substrate 10, including the formation of a symmetrical gate structure over a channel formed between the source and drain regions. As this is a conventional process, further explanation is not required for one of skill in the art to understand and practice the invention.

FIG. 3b shows a conventional deposition process of an interlevel dielectric layer (ILD) 200. The ILD 200 is planarized and etched back to a top of the gate electrode 100.

In FIG. 3c, the gate electrode 100 is slightly recessed below the ILD 200 to form recess 202. In FIG. 3d, spacers 205 are formed in the recess 202. In FIG. 3e, a mask (not shown) is used to protect one edge of the spacer, while an etching process is performed on the other edge of the spacer to remove a portion thereof. The etching may be any conventional etching processes such as, for example, Reactive Ion Etching (RIE). This results in a spacer 205a on one side of the gate electrode 100, preferably the source side of the gate electrode in order to protect this side during subsequent processing steps.

In FIG. 3f, the gate electrode 100 is recessed or etched back on the drain side of the structure. This can be accomplished using any conventional etching process, while the spacer 205a protects the side of the gate structure, closer to the source side. This forms an asymmetrical gate structure. Those of skill in the art should understand that the asymmetrical gate structure could take the form of other shapes by using the processing steps described herein. For example, it is possible to form a multiple step structure by using additional recessing and masking steps as discussed herein.

In FIG. 3g, the spacer and ILD is removed using conventional processes. FIG. 3h shows the formation of contacts 105 in an ILD 300. The contacts 105 can be formed in a conventional process. For example, the ILD is deposited using a conventional deposition method. Using a conventional lithographic and etching process, trenches are formed in the ILD and then metal or a metal alloy is deposited within the trenches, in contact with the source and drain regions.

The method as described above is used in the fabrication of integrated circuit chips. If the invention is a semiconductor chip: The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, perations, elements, components, and/or groups thereof.

The corresponding structures, materials, acts, and equivalents of all means or step plus function elements in the claims below, if applicable, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated. While the invention has been described in terms of embodiments, those of skill in the art will recognize that the invention can be practiced with modifications and in the spirit and scope of the appended claims.

What is claimed is:

1. A structure comprising an asymmetrical gate electrode with a taller side near a source region and a shorter side near a drain region and contacts on either side of the gate electrode, connecting to the source region and the drain region.

2. The structure of claim 1, wherein the asymmetrical gate electrode is configured in a stepped pattern

3. The structure of claim 2, wherein the asymmetrical gate electrode is configured in a multiple stepped pattern.

4. A method comprising:
forming source region and drain region in a substrate;
forming a symmetrical gate structure over a channel formed between the source region and the drain region;
depositing a material on the substrate and planarizing the material to a top of the symmetrical gate structure;
recessing the symmetrical gate structure to below a surface of the material;
forming spacers in the recess;
protecting one edge of the spacer on a source side of the symmetrical gate structure while etching another edge of the spacer to remove a portion thereof on a drain side of the symmetrical gate structure; and
recessing the symmetrical gate structure on a side closest to the drain region while the another edge of the spacer protects the symmetrical gate structure on a side closest to the drain region to form an asymmetrical gate electrode.

5. The method of claim 4, further comprising removing the spacer and the material.

6. The method of claim 5, further comprising forming contacts in contact with the source region and the drain region.

7. The method of claim 6, wherein the material is an interlevel dielectric material.
